(19) United States
(12) Patent Application Publication
(10) Pub. No.: US 2011/0318651 A1
(43) Pub. Date: Dec. 29, 2011

(54) THERMOELECTRIC GENERATOR

(75) Inventors: Klaus Leitner, Ludwigshafen (DE); Martin Schulz-Dobrick, Mannheim (DE); Colin God, Graz (AT); Olivia Moser, Graz (AT); Cornelia Bayer, Graz (AT); Stefan Koller, Graz (AT)

(73) Assignee: BASF SE, Ludwigshafen (DE)

(21) Appl. No.: 13/168,273

(22) Filed: Jun. 24, 2011

Related U.S. Application Data
(60) Provisional application No. 61/358,042, filed on Jun. 24, 2010.

(51) Int. Cl. H01M 10/0562; B05D 5/12; H01M 10/04; C23C 14/48

(52) U.S. Cl. 429/320; 427/523; 427/58; 429/304; 429/322

(57) ABSTRACT

The invention relates to a cathode (A) for lithium ion accumulators, comprising
(a1) at least one current collector,
(a2) at least one layer comprising at least one cathode-active material which stores/releases lithium ions,
   at least part of layer (a2) having been compacted and/or the side of layer (a2) facing the anode having at least one layer (a3) which comprises at least one solid electrolyte which conducts lithium ions, said solid electrolyte being selected from the group consisting of inorganic solid electrolytes and mixtures thereof and being insoluble in the electrolyte system (B) used in the lithium ion accumulator,
   to lithium ion accumulators comprising the cathode (A) and to a process for producing the cathode (A).

The present invention claims the benefit of pending U.S. provisional patent application Ser. No. 61/358,042 filed Jun. 24, 2010.

The present invention relates to a cathode for lithium ion accumulators with improved cycle stability, and to lithium ion accumulators which comprise this cathode. The inventive cathodes can be used to achieve long-life lithium ion accumulators with high cell voltage.

There is a great demand for batteries and accumulators as power sources in portable devices such as digital cameras and notebooks. For this purpose, the batteries and accumulators should have a maximum energy density and a maximum lifetime. An additional factor for the accumulators is that they should be able to pass through a maximum number of charge/discharge cycles without any decrease in their capacity.

Lithium has one of the highest negative potentials of all chemical elements. Batteries and accumulators with a lithium-based anode therefore have very high cell voltages and very high theoretical capacities. Among the lithium-based accumulators, lithium ion accumulators have particular advantages, since they do not comprise any metallic lithium which can react with the electrolytes present in the accumulators and thus lead to safety problems. The cell voltage in a lithium ion accumulator is generated by the movement of lithium ions.

The anode materials used for lithium ion accumulators are typically compounds which can store and release lithium ions, for example graphite.

Customary cathode-active materials are lithium metal oxides such as LiCoO₂, LiNiO₂ and LiMn₂O₄. The electrochemical reactions of these materials proceed typically at a potential of about 3 to 4 V. One way of increasing the performance of lithium ion accumulators is to use cathode-active materials for which the electrochemical reactions proceed at higher potentials. One example of such a cathode-active material is LiNi_{0.5}Mn_{1.5}O₄, the electrochemical reactions of which proceed within a voltage window from 4.5 to 4.9 V. A problem with the use of such cathode-active materials is that the known organic electrolyte systems typically used in lithium ion accumulators are oxidatively destroyed at voltages above 4.5 V. This irreversibly destroys the electrolyte components, and the gases which form generate a considerable pressure rise, which can impair the safety of the lithium ion accumulator since explosion of the accumulator is possible from a certain pressure.

In the case of lithium ion accumulators which comprise LiPF₆ as a conductive salt and tetravalent manganese in the cathode-active material, a further problem which additionally occurs is the partial dissolution of the cathode-active layer. When an electrolyte comprises traces of water, the reaction of the water with the conductive salt forms hydrofluoric acid, as a result of which the manganese is leached out of the active layer as divalent manganese and deposited on the anode.

S. Patoux et al., J. of Power Sources 189 (2009), pages 344-352 describes a solution to this problem, in which an additive added to the liquid electrolyte is said to protect the interface between the cathode and the electrolyte and inhibit self-discharge. The additive forms a protective layer between cathode and electrolyte. However, it is possible in this way to use only a limited selection of materials as the protective layer.

Y. Fan et al., Electrochimica Acta 52 (2007), pages 3870-3875 and H. M. Wu et al., J. of Power Sources 195 (2010), pages 2909-2913 disclose coating nanoparticles of the cathode-active material with SiO₂, ZrO₂ or ZrP₂O₇, and using these coated particles as cathode-active material. The production of the coated particles is in principle comparatively complex; in addition, the individual particles are separated from one another by the coating applied in each case, which results in an increase in the internal resistance in the cathode.

It is an object of the present invention to provide cathodes for lithium ion accumulators, and lithium ion accumulators with a long lifetime and a high number of charge/discharge cycles with a comparatively small decrease in capacity. More particularly, the inventive cathodes should make it possible to produce lithium ion batteries which have cell voltages of at least 4 V, especially of at least 4.5 V, and likewise have a long lifetime.

This object is achieved in accordance with the invention by a cathode (A) for a lithium ion accumulator, comprising

(a1) at least one current collector,
(a2) at least one layer comprising at least one cathode-active material which stores/releases lithium ions,
at least part of layer (a2) having been compacted and/or the side of layer (a2) facing the anode having at least one layer (a3) which comprises at least one solid electrolyte which conducts lithium ions, said solid electrolyte being selected from the group consisting of inorganic solid electrolytes and mixtures thereof and being insoluble in the electrolyte system (B) used in the lithium ion accumulator,
and by lithium ion accumulators comprising the above-described cathodes (A),

In the inventive cathodes for lithium ion accumulators, the contact between the cathode-active material present in the cathode and the electrolyte system is reduced significantly, and the aging phenomena caused by this contact, such as significant capacity decrease or pressure rise, are reduced. When at least some of the cathode-active material present in layer (a2) is in compacted form, the compacted layer has a lower porosity and gives less area for attack to a liquid electrolyte. In the second alternative, the surface of the layer comprising the cathode-active material is protected with a layer of a solid electrolyte, and screens the cathode-active material completely from direct contact with the liquid electrolyte system. Compared to protective layers which do not conduct lithium ions, the inventive protective layers have a high lithium ion conductivity on lithium-conducting solid electrolytes, such that the layer between liquid electrolyte system and cathode-active material can be made thicker and denser, i.e. less porous, with an equal increase in the resistance to the flow of the lithium ions. As a result, inhibition of electrolyte decomposition is significantly better. It is particularly advantageous to combine the two alternatives, in which case cathodes with particularly good properties are obtained when a layer (a3) comprising at least one lithium ion-conducting solid electrolyte is first applied to the at least one, as yet uncompacted layer (a2), then layers (a2) and (a3) are compacted together, for example by thickness reduction by means of calendering, and then a further layer comprising at least one lithium ion-conducting solid electrolyte is applied.

In the case of use of the inventive cathodes, the liquid electrolyte system used in the lithium ion accumulators need only be matched to the anode. In the case of the conventional anode-active materials with a potential between 3 and 4 V, it is possible in principle to use, in the inventive cathodes, all cathode-active materials which have a potential above 4.5 V since direct contact between these materials and the liquid electrolyte system is reduced significantly. It is therefore possible, in spite of the problems already addressed with regard to the oxidative stability of the electrolyte systems, to use the conventionally usable electrolyte systems also with cathode-active materials having a potential of 4.5 V or more. Lithium ion accumulators comprising the inventive cathodes have more stable capacities in long-term tests. In addition, the inventive lithium ion accumulators are more stable to temperature increases.

The invention is illustrated in detail hereinafter.

In the context of the invention, an “accumulator” means a rechargeable electrochemical cell, also known as a secondary cell.

In the context of the present invention, “anode” refers to the negatively charged electrode of the electrochemical cell. At the negative electrode, reduction takes place in the course of charging of an accumulator; in a lithium on accumulator, lithium ions are stored at the anode in the course of the charging operation. In the course of discharge, oxidation takes place at the negative electrode; in a lithium ion accumulator, the lithium ions stored are released at the same time. The counterelectrode is called the “cathode”.

In the context of the present invention, the term “anode-active material” or “cathode-active material” refers to materials, compounds and/or substances which can be used as electrochemically active materials/compounds/substances in the anode or the cathode of lithium ion accumulators, especially materials/compounds/substances which store/release lithium ions. These may be individual compounds, materials or substances, but mixtures of different materials/compounds/substances may also be encompassed thereby.

The electrodes of the inventive lithium ion accumulator typically comprise a current collector, which facilitates electron flow between the particular electrode and the external circuit. The current collector frequently also serves as a substrate, on which at least one layer comprising at least one anode-active or cathode-active material has been applied. In the case of the inventive cathode (A), the at least one layer (a2) comprising at least one cathode-active material has been applied on the optionally present current collector. The current collector is typically composed of metal, for example in the form of a metal foil or of a metal grid. The metal used is preferably nickel, aluminum, stainless steel, copper and the like. For the cathode, preference is given in accordance with the invention to an aluminum current collector; for the anode, copper is preferred as the material for the current collector.

According to the invention, it is possible in principle to use all materials known to be cathode-active to the person skilled in the art in the at least one layer (a2). These include lithium-absorbing and -releasing metal oxide compositions. For instance, it is possible to use LiCoO₂, LiNiO₂, LiMn₂O₂, LiMnO₄, spinels of the LiMₓMn₂₋ₓO₄ type with M selected from the group consisting of Cr, Ni, Co, Cu and/or Fe, where 0≦x≦1, lithium-comprising mixed oxides with Ni, Mn and/or Co with further metals selected from Mg, Zn, Al, Ga, W, Zr, Ti, Ca, Ce, Y and/or Nb, and LiFePO₄ and mixtures thereof, preference being given to cathode-active materials whose electrochemical reactions proceed at least 3 V, preferably at least 4.2 V and more preferably at least 4.5 V. Particular preference is given in accordance with the invention to using the spinels of the LiMₓMn₂₋ₓO₄ type with M selected from the group consisting of Cr, Ni, Co, Cu and/or Fe and mixtures thereof, where 0≦x≦1.

In addition to the at least one cathode-active material, the at least one layer (a2) may comprise binders such as polyvinylidene fluoride, polyethylene oxide, polyethylene, polypropylene, polytetrafluoroethylene, polyacrylates, ethylene-propylene-diene monomer copolymer (EPDM) and mixtures and copolymers thereof. If layer (a2) comprises a binder, it is present typically in a concentration of 1 to 20% by weight, preferably in a concentration of 2 to 15% by weight, based on the total weight of the at least one layer (a2).

In addition, the at least one layer (a2) may comprise one or more electrically conductive materials, for example graphite, carbon black, carbon fibers including graphite fibers or carbon nanotubes, metal powders such as silver powder, metal fibers such as stainless steel fibers and the like, and mixtures thereof. If the cathode comprises one or more conductive materials of this kind, they are present typically in a concentration of 1 to 25% by weight, preferably of 2 to 15% by weight, based on the total weight of the at least one layer (a2). The electrically conductive material(s) is/are different from the cathode-active materials.

If the cathode has a flat current collector (a1), it may have one or more layers (a2) on one side or on both sides.

In one alternative of the inventive cathode (A), at least part of the at least one layer (a2) is in compacted form. “Compacted” in the context of the invention means that the density has been increased by the action of external forces, such that the compacted portion of the at least one layer (a2) has a higher density than before the action of the external forces; preferably, the entire at least one layer (a2) is in compacted form.

Preferably in accordance with the invention, the compaction increases the density by at least 10%, more preferably by at least 30%, even more preferably by at least 50% and especially preferably by at least 60%, based on the density before action of the external forces. The external forces which cause the compaction can be applied, for example, by pressing, rolling and/or calendering. Typically, the compaction of at least part of or the entire layer (a2) and the optionally present layer (a3) is accompanied by a reduction in thickness; preference is given in accordance with the invention to a reduction in thickness of the at least one layer (a2) and of the optionally present layer (a3) by at least 10%, more preferably by at least 30%, even more preferably by at least 50% and especially preferably by at least 60%, based on the total thickness of the at least one layer (a2) and of the optionally present layer (a3) before the action of the external forces. The compaction lowers the porosity of the layer (a2); the cathode-active material present within the at least one layer (a2) is less easily accessible to the harmful electrolyte. Lithium ion accumulators in which the at least one layer (a2) is in compacted form exhibit a reduced decrease in capacity compared to lithium accumulators in which the layer comprising the cathode-active material is in noncompacted form. In the course of compaction, the cathode is typically in the dried state; the percentage values reported for the reduction in density or thickness likewise relate to the cathode in the dried state. “Dried state” means that any solvent and/or volatile assistants used in application of layer (a2) and optionally (a3) have been removed.

In the second alternative of the invention, the cathode has at least one layer which has been applied to (a2) and comprises at least one lithium ion-conducting solid electrolyte. The at least one layer (a3) has been applied in accordance with the invention such that the at least one cathode-active material present in the cathode is protected from contact with the liquid electrolyte system; layer (a3) separates and protects the at least one cathode-active material present in (a2) from the lithium ion-conducting, liquid electrolyte system present in the lithium ion accumulator. The at least one layer (a3) has been applied on the side of the layer (a2) which faces the anode or the liquid electrolyte system between the anode and the cathode. If the cathode has at least one layer (a2) on each side, each of which face the anode or the liquid electrolyte system between the anode and the cathode, for example when the lithium ion accumulator is in the form of a winding, each layer (a2) may be provided with a layer (a3).

According to the invention, the at least one lithium ion-conducting solid electrolyte is selected from inorganic solid electrolytes and mixtures thereof. Among the inorganic solid electrolytes are firstly oxides of metals and semimetals which are known per se as nonconductors but can conduct lithium ions when the layer of the oxide is sufficiently thin, which means that these layers, in accordance with the invention, have a thickness of 1 nm to 50 micrometers, the thickness preferably being 10 nm to 4 micrometers. The oxides of metals and semimetals which can be used in this way include, for example, Al₂O₃, SiO₂, ZrO₂ and TiO₂.

In addition, the inorganic solid electrolytes which can be used in accordance with the invention are the ceramic, glass-like and glass-ceramic solid electrolytes which are known by the person skilled in the art to generally conduct lithium ions. These ceramic, glass-like and glass-ceramic solid electrolytes are preferably selected from oxides, sulfides, phosphates and mixtures thereof. They also include the lithium ion conductors known as LISICON (Lithium Super Ionic Conductor) and thio-LISICON. The ceramic, glass-like and glass-ceramic solid electrolytes include the group consisting of Li₂S—P₂S₅, Li₂S—P₂S₅—Li₄SiO₄, Li₂S—Ga₂S₃—GeS₂, Li₂S—Sb₂S₃—GeS₂, Li_{3.25}Ge_{0.25}P_{0.75}S₄, Li_{4.2}Ge_{0.8}Ga_{0.2}S₄, Li_{2.2}Zn_{0.1}Zr_{1.9}S₃, Li₂S—GeS₂—P₂S₅, Li₂S—SiS₂—Al₂S₃, Li₂S—SiS₂—P₂S₅, SiS₂, Li₃PO₄—Li₂S—SiS₂, Li₂S—SiS₂—Li₄SiO₄, (La,Li)TiO₃ such as Li_{0.5}La_{0.5}TiO₃, Li₂₋ₓMg₂ₓTiO_{3+x, Li}₂ₓZn₂₋₃ₓTi₁₊ₓO₄, Li₅La₃Ta₂O₁₂, Li₆La₂CaTa₂O₁₂, Li₆La₂CaNb₂O₁₂, Li₆La₂SrNb₂O₁₂, Li₂Nd₃TeSbO₁₂, Li₃BO_{2.5}N_{0.5}, Li₃SiAlO₈, Li₂₊₂ₓZn₁₋ₓGeO₄, Li₁₊ₓAlₓGe₂₋ₓ(PO₄)₃, Li₁₊ₓTi₂₋ₓAlₓ(PO₄)₃, Li₁₊ₓTi₂₋ₓAlₓSi_{y}(PO₄)_{3-y}, LiTi_{0.5}Zr_{1.5}(PO₄)_{3-y}, LiₓAlZr[PO₄]₃ and Li₃Fe₂(PO₄)₃.

Preferably in accordance with the invention, the at least one lithium ion-conducting solid electrolyte is selected from the group consisting of the oxides Al₂O₃, SiO₂, ZrO₂ and TiO₂ with a layer thickness of 1 nm to 50 micrometers, preferably of 10 nm to 4 micrometers, and the ceramic, glass-like or glass-ceramic solid electrolytes Li₂S—P₂S₅, Li₂S—P₂S₅—Li₄SiO₄, Li₂S—Ga₂S₃—GeS₂, Li₂S—Sb₂S₃—GeS₂, Li_{3.25}Ge_{0.25}P_{0.75}S₄, Li_{4.2}Ge_{0.8}Ga_{0.2}S₄, Li_{2.2}Zn_{0.1}Zr_{1.9}S₃, Li₂S—GeS₂—P₂S₅, Li₂S—SiS₂—Al₂S₃, Li₂S—SiS₂—P₂S₅, Li₂S—SiS₂, Li₃PO₄—Li₂S—SiS₂, Li₂S—SiS₂—Li₄SiO₄, (La,Li)TiO₃ such as Li_{0.5}La_{0.5}TiO₃, Li₂₋ₓMg₂ₓTiO₃₊ₓ, Li₂ₓZn₂₋₃ₓTi₁₊ₓO₄, Li₅La₃Ta₂O₁₂, Li₆La₂CaTa₂O₁₂, Li₆La₂CaNb₂O₁₂, Li₆La₂SrNb₂O₁₂, Li₂Nd₃TeSbO₁₂, Li₃BO_{2.5}N_{0.5}, Li₉SiAlO₈, Li₂₊₂ₓZn₁₋ₓGeO₄, Li₁₊ₓAlₓGe₂₋ₓ(PO₄)₃, Li₁₊ₓTi₂₋ₓAlₓ(PO₄)₃, Li₁₊ₓTi₂₋ₓAlₓ(PO₄)₃, Li₁₊ₓTi₂₋ₓAlₓSi_{y}(PO₄)_{3-y}, LiTi_{0.5}Zr_{1.5}(PO₄)_{3-y}, LiₓAlZr[PO₄]₃ and Li₃Fe₂(PO₄)₃.

The at least one layer (a2) may comprise one solid electrolyte or more than one solid electrolyte, and/or one, two or more layers which each comprise one or more solid electrolytes.

An overview of inorganic lithium ion-conducting solid electrolytes for lithium ion batteries can be found in J. W. Fergus, J. of Power Sources 195 (2010), p. 4554-4569.

Lithium ion accumulators comprise, as well as cathode and anode, at least one lithium ion-conducting electrolyte system, very frequently a liquid electrolyte system (B). The electrolyte system is arranged between the anode and cathode and serves to transport the lithium ions between anode and cathode. According to the invention, the at least one lithium ion-conducting solid electrolyte present in (a3) is insoluble in the liquid electrolyte system (B) used for the lithium ion accumulator. In this way, the protective layer (a3) comprising the solid electrolyte is not attacked by the liquid electrolyte system and protects the cathode-active material from contact with the liquid electrolyte system. According to the invention, “insoluble” means that at least 1% by weight, preferably at least 50% by weight, more preferably at least 90% by weight and especially at least 99% by weight of the at least one lithium ion-conducting solid electrolyte is insoluble in the liquid electrolyte system (B), based on the total weight of dissolved solid electrolyte and undissolved solid electrolyte.

Conversely, the at least one layer (a3) comprising solid electrolyte should absorb a minimum amount of the solvent(s) present in the liquid electrolyte system; the layer (a3) should preferably absorb not more than 99% by weight, more preferably not more than 50% by weight, especially preferably not more than 10% by weight and especially not more than 1% by weight of solvent(s) from the liquid electrolyte system, based on the total weight of the layer (a3), before contact with the liquid electrolyte system. The layer (a3) should thus be inert as far as possible toward the liquid electrolyte system and the solvent(s) present therein, which means that it should neither be partially dissolved or even dissolved by the liquid electrolyte system, nor should the layer (a3) absorb solvents present in the liquid electrolyte system, for example by swelling and/or diffusion, and pass it on to the cathode-active material.

In this third alternative of the inventive cathode (A), at least a portion of, preferably all of, the at least one layer (a2) is in compacted form, and the side of the at least one layer (a2) facing the anode or liquid electrolyte system has at least one layer (3) which comprises at least one solid electrolyte which conducts lithium ions, said solid electrolyte being selected from the group consisting of inorganic and polymeric solid electrolytes and mixtures thereof, and being insoluble in the electrolyte system (B) used in the lithium ion accumulator. It is particularly preferred when at least one layer (a3) has been applied to the uncompacted layer (a2), such that a portion of the Li-conducting solid electrolyte present in the layer (a3) penetrates into pores possibly present in the layer (a2), when the layers (a2) and (a3) have been compacted together and then a further layer (a3) has been applied, These cathodes exhibit particularly good stability in long-term tests.

A further preferred embodiment of the invention relates to the cathode (A) for a lithium ion accumulator comprising

(a1) at least one current collector,
(a2) at least one layer comprising at least one cathode-active material which stores/releases lithium ions,
at least part of layer (a2) having been compacted and the side of layer (a2) facing the anode optionally having at least one layer (a3) which comprises at least one solid electrolyte which conducts lithium ions, said solid electrolyte being selected from the group consisting of inorganic solid electrolytes and mixtures thereof and being insoluble in the electrolyte system (B) used in the lithium ion accumulator. The entire layer (a2) present is preferably in compacted form; more preferably, in the presence of the optionally present layer (a3), both layers are compacted in the production of the cathode. The cathode (A) may optionally have a further layer (a3) on the preceding layer (a3), which is typically applied after compaction of (a2) and (a3).

A further preferred embodiment of the invention relates to the cathode (A) for a lithium ion accumulator comprising

(a1) at least one current collector,
(a2) at least one layer comprising at least one cathode-active material which stores/releases lithium ions,
the side of layer (a2) facing the anode having at least one layer (a3) which comprises at least one solid electrolyte which conducts lithium ions, said solid electrolyte being selected from the group consisting of inorganic solid electrolytes and mixtures thereof and being insoluble in the electrolyte system (B) used in the lithium ion accumulator, and optionally at least part of layer (a2) having been compacted. Preferably the entire layer (a2) is present in compacted form; more preferably, (a2) and optionally (a3) are compacted in the production of the cathode. The cathode (A) may optionally have a further layer (a3) on the preceding layer (a3), which is typically applied after compaction of (a2) and (a3).

The invention further provides a process for producing the above-described cathode (A) comprising the steps of
(i) providing at least one layer (a2) comprising at least one cathode-active material and at least one current collector,
(ii) optionally applying at least one layer (a3) comprising at least one solid electrolyte to layer (a2),
(iii) optionally compacting layer (a2) and the optionally present layer (a3) and
(iv) optionally applying at least one layer (a3) comprising at least one solid electrolyte to layer (a2),
   wherein at least one of steps (ii) to (iv) is performed, and the cathodes (A) producible by this process.

According to which alternative or embodiment of the cathode (A) is to be produced, the process comprises only one of the three steps, two of the three steps or all three steps (ii) to (iv). Individual or else all steps may be repeated.

Step (i) is known in principle to those skilled in the art. For example, the at least one cathode-active material, optionally mixed with binders and further conductive assistant, can be processed mixed with one or more solvents to give a dispersion, which is applied to one or both surfaces of a current collector, for example of an aluminum foil, and then dried.

In step (ii), at least one layer (a3) comprising at least one solid electrolyte is optionally applied to the prepared cathode comprising at least one layer (a2) comprising at least one cathode-active material. For this purpose, a dispersion of the solid electrolyte in a dispersion medium is typically produced, and the latter is applied to the at least one layer (a2). This can be accomplished, for example, by atmospheric pressure ion deposition, inkjet printing, or by pneumatic means, for example by spraying. This can be done using organic solvents as dispersants, for example ethanol or propylene carbonate.

Atmospheric pressure ion deposition (APID) is based on the principle of pumping a solution of the material to be processed through a capillary, to which a high electrostatic potential with respect to its environment is applied. This results in electrostatic spraying of the solution and in the formation of ions of the material by the mechanism of electrospray ionization. The pseudomolecular ions formed under atmospheric pressure are subsequently deposited in a controlled manner onto a substrate.

A significant difference from other related methods for applying thin layers, such as inkjet printing, is that the ions in APID hit the target “dry”, i.e. without dispersant. This has the advantage that no solvent hits the surface to be coated. If solvent were still present on impact, this could partly dissolve the layers already formed by this time and destroy them. Such processes can be observed, for example, in spin-coating.

Step (iii) has already been described above. This involves compacting at least part of layer (a2), preferably the entire layer (a2). If step (ii) has been carried out beforehand, preferably both layers (a2) and (a3) are compacted in step (iii).

Step (iv) is performed in analogy to step (ii).

The process described can also be used to produce cathodes with several sequences of layers (a2) and (a3), in which at least one further step (v) is carried out, in which at least one further layer (a2) comprising at least one cathode-active material is applied. Thereafter, according to the desired result, steps (ii) to (iv) and optionally also (v) can be repeated.

The invention further provides lithium ion accumulators comprising
(A) a cathode as described above,
(B) a lithium ion-conducting liquid electrolyte system and
(C) an anode.

The liquid lithium ion-conducting electrolyte system preferably comprises
(b1) at least one nonaqueous solvent and
(b2) at least one lithium ion-conducting electrolyte salt.

The at least one nonaqueous solvent can be selected from the customary solvents which are known to those skilled in the art as solvents for electrolyte systems in lithium ion batteries, for example from N-methylacetamide, acetonitrile, carbonates, sulfolanes, sulfones, N-substituted pyrrolidones, acyclic ethers, cyclic ethers, xylene, polyether and siloxanes. The carbonates include methyl carbonate, ethyl carbonate and propyl carbonate; the polyethers include, for example, glymes comprising diethylene glycol dimethyl ether (diglyme), triethylene glycol dimethyl ether (triglyme), tetraethylene glycol dimethyl ether (tetraglyme) and higher glymes, and also ethylene glycol divinyl ether, diethylene glycol divinyl ether, triethylene glycol divinyl ether, dipropylene glycol dimethyl ether and butylene glycol ether.

Acyclic ethers comprise, for example, dimethyl ether, dipropyl ether, dibutyl ether, dimethoxymethane, trimethoxymethane, dimethoxyethane, triethoxymethane, 1,2-dimethoxypropane and 1,3-dimethoxypropane.

The cyclic ethers comprise tetrahydrofuran, tetrahydropyran, 2-methyltetrahydrofuran, 1,4-dioxane, trioxane and dioxolanes.

Preferably in accordance with the invention, the nonaqueous solvents used for the electrolyte system are ethylene carbonate, propylene carbonate and mixtures thereof, The lithium ion-comprising electrolyte salts used may be the customary electrolyte salts known to those skilled in the art for use in lithium batteries and lithium accumulators. For example, the at least one electrolyte salt (b2) comprising lithium ions can be selected from the group consisting of LiPF₆, LiBF₄, LiB(C₆H₅)₄, LiSbF₆, LiAsF₆, LiClO₄, LiCF₃SO₃, Li(CF₃SO₂)₂N, LiC₄F₉SO₃, LiAlO₄, LiAlCl₄, LiN(CₓF₂ₓ₊₁SO₂)(C_{y}F_{2y+1}SO₂), LiSCN, LiCl, LiBr and Lil, and mixtures thereof.

In addition, the inventive lithium ion accumulator comprises an anode (C). It is possible to use any anodes typically usable in lithium ion accumulators. Typically, the anode comprises at least one anode-active material which is capable of storing and releasing lithium ions. Suitable for this purpose are especially lithium intercalation compounds based on crystalline and/or amorphous carbon, Si, SnO₂ and Li₄Ti₆O₁₂. Carbon-based compounds are, for example, graphite, graphene, carbon nanotubes and acetylene black.

In addition, it is possible to use Si, Al, Sn, Sb and WO₂ as host compounds for the lithium ion intercalation compounds for the anode.

The inventive lithium ion accumulator may further comprise a separator which separates the anode space from the cathode space. Typically, the separator is a porous conductive or insulating material which separates or insulates the anode region and the cathode region from one another, and allows the transport of ions through the separator between the anode space and the cathode space of the cell. The separator is typically selected from the group consisting of porous glass, porous ceramic and porous polymers.

The invention is illustrated further hereinafter with reference to examples. In all examples cited, the anode used was a commercial anode based on lithium titanate as an active material. The lithium titanate originates from Südchemie; the electrode was composed of 88% by weight of active material, 7% by weight of “Kynar 761” PVdF (polyvinylidene fluoride) and 5% by weight of Super-P (conductive black). The cathode-active material used in all examples was LiNi_{0.5}Mn_{1.5}O₄ on aluminum foil as a current collector. The LiNi_{0.5}Mn_{1.5}O₄ was from BASF; the composition of the electrode was 88% by weight of active material, 7% by weight of “Kynar 761” PVdF (binder) and 5% by weight of Super-P (conductive black). The liquid electrolyte system consisted in each case of a mixture of ethylene carbonate/propylene carbonate (1:1, V:V) with LiPF₆ as a conductive salt in one molar solution. The electrochemical reactions of such cells take place between 4.5 and 4.9 V.

The specific discharge capacities for the cathodes from examples 1 to 8 in the constant-current cycling were determined between 3.5 and 4.9 V with a cutoff voltage of 4.9 V (vs. Li/Li⁺). The charging and discharging rate was 10 in each case, and maintenance charging was carried out for 0.25 hour in each case. In examples 1 to 6, the temperature was kept constant. The results are shown in table 1; in each case, the absolute values of the specific discharge capacities, and the specific discharge capacities in % normalized to the first cycle, are shown. In examples 7 and 8, under otherwise the same test conditions, the temperature was increased from 25 to 40° C. after 80 hours of analysis time, and lowered again to 25° C. after 120 hours of analysis time. During all of the analyses of examples 7 and 8, pressure was measured in the cell, which serves as an indicator for possible occurrence of oxidative destruction of the electrolyte. These measurements also give information about the thermal stability of the cathodes. The results can be seen in table 2.

### EXAMPLE 1

### Comparative

The cathode has only one uncompacted layer of the cathode-active material. Neither a layer (a3) comprising a lithium ion-conducting solid electrolyte is present, nor is the layer (a2) in compacted form.

### EXAMPLE 2

### Inventive

The cathode was compacted by repeated calendering between two steel rollers. The electrode was repeatedly pulled through the calender until the desired degree of compaction had been attained. The total layer thickness of the calendered cathode was 40.75 micrometers; the layer thickness of the active material (a2) was 11.25 micrometers. The calendering reduced the thickness of layer (a2) by 47.1%.

### EXAMPLE 3

### Inventive

A thin SiO₂ protective layer (layer (a3)) was applied by means of APID to a calendered cathode according to example 2. For this purpose, the fine SiO₂ was dispersed in ethanol and then applied by means of the APID process. After calculation from the amount applied, the layer thickness of the SiO₂ layer was 1 micrometer. The thickness reduction as a result of the calendering was 47.1%; the thickness of the cathode-active layer (a2) was 11.25 micrometers.

### EXAMPLE 4

### Inventive

The cathode was compacted significantly by calendering, as described in example 2.

The total layer thickness of the calendered cathode was 37 micrometers; the layer thickness of the active material (a2) was 7.5 micrometers. The calendering reduced the thickness of layer (a2) by 68.6%.

### EXAMPLE 5

### Inventive

A thin SiO₂ protective layer (a3)) was applied by means of APID to the significantly calendered cathode from example 4 (layer (a3)). The layer thickness of the SiO₂ layer was, after calculation from the amount applied, 1 micrometer. The layer thickness of the active material (a2) was 7.5 micrometers. The calendering reduced the thickness of layer (a2) by 68.6%.

### EXAMPLE 6

### Inventive

First, a layer of thin SiO₂ protective layer (a3)) was applied by means of APID to an uncalendered cathode. Subsequently, the cathode (layers (a2) and (a3)) was calendered and, finally, a further thin SiO₂ protective layer (further layer (a3)) was applied by means of APID.

TABLE 1

| Example | Cycle | 1 | 2 | 10 | 50 | 70 | 100 |
|---|---|---|---|---|---|---|---|
| 1 | Discharge | 518.58 | 520.07 | 482.22 | 251.13 | 186.34 | 168.65 |
| (comparative) | capacity | | | | | | |
| | [mAhg⁻¹] | | | | | | |
| | [%] | 100 | 100.29 | 92.99 | 48.43 | 35.93 | 32.52 |
| 2 | Discharge | 537.64 | 536.39 | 520.6 | 485.21 | 465.13 | 451.18 |
| (inventive) | capacity | | | | | | |
| | [mAhg⁻¹] | | | | | | |
| | [%] | 100 | 99.77 | 96.83 | 90.25 | 86.51 | 83.92 |
| 3 | Discharge | 512.35 | 519.56 | 506.88 | 483.39 | 466.98 | 432.07 |
| (inventive) | capacity | | | | | | |
| | [mAhg⁻¹] | | | | | | |
| | [%] | 100 | 101.41 | 98.93 | 94.35 | 91,14 | 84.33 |
| 4 | Discharge | 580.37 | 587.09 | 570.44 | 509.9 | 475.02 | 464.22 |
| (inventive) | capacity | | | | | | |
| | [mAhg⁻¹] | | | | | | |
| | [%] | 100 | 101.16 | 98.29 | 87.86 | 81.85 | 79.99 |
| 5 | Discharge | 538.79 | 536.66 | 534.83 | 486.76 | 475.71 | 460.55 |
| (inventive) | capacity | | | | | | |
| | [mAhg⁻¹] | | | | | | |
| | [%] | 100 | 99.6 | 99.27 | 90.34 | 88.29 | 85.48 |
| 6 | Discharge | 604.17 | 626.96 | 641.9 | 610.19 | 597.91 | 583.65 |
| (inventive) | capacity | | | | | | |
| | [mAhg⁻¹] | | | | | | |
| | [%] | 100 | 103.77 | 106.24 | 101 | 98.96 | 96.6 |

Both the compaction of layer (a2) and the application of a layer (a3) of an inorganic lithium ion-conducting solid electrolyte lead to a distinct improvement in stability of the inventive cathodes. When layer (a2) is in compacted form and the cathode additionally comprises a layer (a3) of an inorganic lithium ion-conducting solid electrolyte, a further improvement is achieved. The best result is exhibited by the cathode in which a layer (a3) was applied to the uncompacted layer (a2), both layers were compacted together and a further layer (a3) was applied. This cathode exhibits the highest specific capacity and the smallest change in capacity of the cathodes tested.

### EXAMPLE 7

### Comparative

A cathode according to example 1 was analyzed in an impervious lithium ion accumulator, and the pressure existing in the cell was measured while changing the temperature. After measurement at 25° C. for 80 hours, the temperature was increased very rapidly to 40° C., kept at 40° C. for 40 hours, and lowered very rapidly to 25° C. after a total of 120 hours of measurement time, and kept at this value until the end of the measurement after a total of 240 hours.

### EXAMPLE 8

### Inventive

A cathode according to example 6 was analyzed in an impervious lithium ion accumulator, and the pressure existing in the cell was measured while changing the temperature. After measurement at 25° C. for 80 hours, the temperature was increased very rapidly to 40° C., kept at 40° C. for 40 hours, and lowered very rapidly to 25° C. after a total of 120 hours of measurement time, and kept at this value until the end of the measurement after a total of 240 hours.

TABLE 2

| | Measurement | | Example 7 | Example 8 |
|---|---|---|---|---|
| Measurement | time | Temperature | Pressure | Pressure |
| point | [hours] | [° C.] | [mbar] | [mbar] |
| 1 | 0 | 25 | 1013.75 | 981.25 |
| 2 | 80 | 25 | 1013.02 | 984.79 |
| 3 | 80 | 40 | 1065.94 | 1033.33 |
| 4 | 120 | 40 | 1085.00 | 1039.69 |
| 5 | 120 | 25 | 1032.08 | 990.42 |
| 6 | 240 | 25 | 1063.85 | 994.58 |

The comparative cathode from example 7 does not exhibit any significant change in the pressure before the temperature increase; after the temperature is increased, the pressure rises continuously, even after the original low temperature of 25° C. has been reestablished. Between measurement points 2 and 3, the pressure increases by 1.8%; between measurement points 5 and 6, the pressure increases by 3.1%; overall, the pressure increases by 5% from establishment of the elevated temperature to the end of measurement. For the inventive cathode from example 8, these values are 0.6%, 0.4% and 1%. The inventive cathode from example 8 thus exhibits a distinct improvement in thermal stability with regard to pressure and hence with respect to oxidative decomposition of the electrolyte.

1. A cathode (A) for lithium on accumulators, comprising
(a1) at least one current collector,
(a2) at least one layer comprising at least one cathode-active material which stores/releases lithium ions,
at least part of layer (a2) having been compacted and/or the side of layer (a2) facing the anode having at least one layer (a3) which comprises at least one solid electrolyte which conducts lithium ions, said solid electrolyte being selected from the group consisting of inorganic solid electrolytes and mixtures thereof and being insoluble in the electrolyte system (B) used in the lithium ion accumulator.

2. The cathode (A) according to claim 1, wherein the inorganic solid electrolytes which conduct lithium ions are selected from oxides of metals and semimetals having a layer thickness of 1 nm to 50 micrometers, and ceramic, glass-like and glass-ceramic solid electrolytes.

3. The cathode (A) according to claim 1, wherein the ceramic, glass-like and glass-ceramic solid electrolytes are selected from oxides, sulfides, phosphates and mixtures thereof.

4. The cathode (A) according to claim 1, wherein the at least one solid electrolyte which conducts lithium ions is selected from the group consisting of the oxides Al₂O₃, SiO₂, ZrO₂ and TiO₂ with a layer thickness of 1 nm to 50 micrometers, and the ceramic, glass-like or glass-ceramic solid electrolytes of the group consisting of Li₂S—P₂S₅, Li₂S—P₂S₅—Li₄SiO₄, Li₂S—Ga₂S₃—GeS₂, Li₂S—Sb₂S₃—GeS₂, Li_{3.25}Ge_{0.25}P_{0.75}S₄, Li_{4.2}Ge_{0.8}Ga_{0.2}S₄, Li_{2.2}Zn_{0.1}Zr_{1.9}S₃, Li₂S—GeS₂—P₂S₅, Li₂S—SiS₂—Al₂S₃, Li₂S—SiS₂—P₂S₅, Li₂S—SiS₂, Li₃PO₄—Li₂S—SiS₂, Li₂S—SiS₂—Li₄SiO₄, (La,Li)TiO₃ such as Li_{0.5}La_{0.5}TiO₃, Li₂₋ₓMg₂ₓTiO₃₊ₓ, Li₂ₓZn₂₋₃ₓTi₁₊ₓO₄, Li₅La₃Ta₂O₁₂, Li₆La₂CaTa₂O₁₂, Li₆La₂CaNb₂O₁₂, Li₆La₂SrNb₂O₁₂, Li₂Nd₃TeSbO₁₂, Li₃BO_{2.5}N_{0.5}, Li₉SiAlO₈, Li₂₊₂ₓZn₁₋ₓGeO₄, Li₁₊ₓAlₓGe₂₋ₓ(PO₄)₃, Li₁₊ₓTi₂₋ₓAlₓ(PO₄)₃, Li₁₊ₓTi₂₋ₓAlₓSi_{y}(PO₄)_{3-y}, LiTi_{0.5}Zr_{1.5}(PO₄)₃, LiₓAlZr[PO₄]₃, Li₃Fe₂(PO₄)₃.

5. The cathode (A) according to claim 1, wherein the at least one cathode-active material is selected from the group consisting of LiCoO₂, LiNiO₂, LiMn₂O₂, LiMnO₂, Li-comprising mixed oxides with Ni, Mn and/or Co with metals selected from Mg, Zn, Al, Ga, W, Zr, Ti, Ca, Ce, Y and/or Nb, LiFePO₄ and spinets of the general formula LiMₓMn₂₋ₓO₄, with M selected from Cr, Ni, Co, Cu and/or Fe, where 0≦x≦1.

6. A process for producing a cathode (A) according to claim 1, comprising the steps of
(i) providing at least one layer (a2) comprising at least one cathode-active material and at least one current collector,
(ii) optionally applying at least one layer (a3) comprising at least one solid electrolyte to layer (a2),
(iii) optionally compacting layer (a2) and the optionally present layer (a3) and
(iv) optionally applying at least one layer (a3) comprising at least one solid electrolyte to layer (a2),
wherein at least one of steps (ii) to (iv) is performed.

7. The process according to claim 6, wherein layer (a2) and the optionally present layer (a3) are compacted in step (iii) by pressing, rolling and/or calendering.

8. The process according to claim 7, wherein the thickness of layer (a2) and of the optionally present layer (a3) is reduced in step (iii) by at least 10%, based on the total thickness of layer (a2) and of the optionally present layer (a3) before compaction.

9. The process according to claim 6, wherein the at least one solid electrolyte is applied in step (ii) and/or (iv) by atmospheric pressure ion deposition, inkjet printing, or by pneumatic means.

10. A lithium ion accumulator comprising
(A) a cathode according to claim 1,
(B) a lithium ion-conducting liquid electrolyte system and
(C) an anode.

11. The lithium ion accumulator according to claim 10, wherein the potential difference between cathode and anode is at least 3 V.

12. The lithium ion accumulator according to claim 10, wherein the anode comprises at least one anode-active material selected from the group consisting of lithium intercalation compounds based on crystalline and/or amorphous carbon, Si, Sb, Al, Sn, WO₂, SnO₂ and Li₄Ti₅O₁₂.

13. The lithium ion accumulator according to claim 10, wherein the liquid lithium ion-conducting electrolyte system comprises
(b1) at least one nonaqueous solvent and
(b2) at least one lithium ion-comprising electrolyte salt.

14. The lithium ion accumulator according to claim 13, wherein the at least one solvent (b1) is selected from the group consisting of N-methylacetamide, acetonitrile, carbonates, sulfones, N-substituted pyrrolidones, acyclic ethers, cyclic ethers, xylene, siloxanes, polyethers and mixtures thereof.

15. The lithium ion accumulator according to claim 13, wherein the lithium ion-comprising electrolyte salt (b2) is selected from the group consisting of LiPF₆, LiBF₄, LiB(C₆H₆)₄, LiSbF₆, LiAsF₆, LiClO₄, LiCF₃SO₃, Li(CF₃SO₂)₂N, LiC₄F₉SO₃, LiAlO₄, LiAlCl₄, LiN(CₓF₂ₓ₊₁SO₂)(C_{y}F_{2y+1}SO₂), LiSCN, LiCl, LiBr and Lil.
